(19) United States
(12) Patent Application Publication
(10) Pub. No.: US 2026/0211049 A1
(43) Pub. Date: Jul. 23, 2026

(54) INSPECTION DEVICE, CONTACT STATUS DETERMINING DEVICE, AND CONTACT STATUS DETERMINING METHOD

(71) Applicant: HIOKI E.E. CORPORATION, Ueda-shi Nagano (JP)

(72) Inventors: Takahiro MURAKAMI, Ueda-shi Nagano (JP); Yoichi NAKAMURA, Ueda-shi Nagano (JP); Yusuke SATO, Ueda-shi Nagano (JP); Masami KITAZAWA, Ueda-shi Nagano (JP)

(21) Appl. No.: 19/137,111

(22) PCT Filed: Nov. 21, 2023
(86) PCT No.: PCT/JP2023/041755

§ 371 Date: Jun. 9, 2025

(30) Foreign Application Priority Data
Dec. 13, 2022 (JP) 2022-198445
Nov. 14, 2023 (JP) 2023-193570

(51) Int. Cl. G01R 31/389; G01R 1/28; G01R 31/367; G01R 31/3842

(52) U.S. Cl. CPC G01R 31/389; G01R 1/28; G01R 31/367; G01R 31/3842

(57) ABSTRACT

A processor that performs determination processing for determining whether a contact state between probes P1 and P2 brought into contact with a positive electrode terminal Tp and a metal layer Lm in a secondary battery DUT having capacitance Cd between the positive electrode terminal Tp and the metal layer Lm is satisfactory or unsatisfactory, a storage 7 that stores a threshold value set to a value equal to or less than a capacitance value of capacitance C3 between the probes P1 and P2 in a non-contact state with the positive electrode terminal Tp and the metal layer Lm, and a capacitance value of the capacitance Cd between the positive electrode terminal Tp and the metal layer Lm, and a processor 6 that measures a capacitance value of capacitance (capacitance obtained by adding the capacitance C3 and the capacitance Cd) between the probes P1 and P2 in a contact state.

### TECHNICAL FIELD

The present invention relates to a contact state determining device for determining a contact state between a pair of probes used in a measurement device or an inspection device for measuring a measured quantity such as a voltage of an inspection target and a pair of determination target portions of the inspection target, and also relates to an inspection device including the contact state determining device, and a contact state determining method.

### BACKGROUND ART

As this type of contact state determining device, the applicant discloses an insulation withstand voltage tester in the following Patent Literature 1. The insulation withstand voltage tester includes a power supply section (a withstand voltage test power supply and an insulation resistance test power supply) for applying a test voltage to an object to be tested, and four probes including probes P1 and P2 for applying voltage and probes P3 and P4 for detecting disconnection, and is configured to be able to perform a withstand voltage test and an insulation resistance test on the object to be tested. In this case, in the insulation withstand voltage tester, the probe P1 for applying voltage is connected to a Hi-side power source terminal of the power supply section via a first wire, the probe P2 for applying voltage is connected to a Lo-side power source terminal of the power supply section via a second wire, the probe P3 for detecting disconnection is connected to the Lo-side power source terminal of the power supply section via a third wire, the probe P4 for detecting disconnection is connected to the second wire L2 via a fourth wire, a Hi-side disconnection voltage detection unit 112 is disposed on the third wire, and a power supply for detecting disconnection and a Lo-side disconnection current detection unit are disposed on the fourth wire. Thus, the contact state (presence or absence of disconnection) of the probes P1 and P2 for applying voltage can be determined based on detection values of the Hi-side disconnection voltage detection unit and the Lo-side disconnection current detection unit.

In addition, the applicant discloses a contact state determining device in the following Patent Literature 2. The contact state determining device includes a current supplier, a voltage detection unit, a detection signal generation unit, a detector, a processor, an output unit, and a storage, and discriminates a contact state between a pair of electrodes of a secondary battery and a pair of probes.

In the contact state determining device, the current supplier supplies an AC inspection current to the secondary battery, and outputs a reference signal having the same frequency and the same phase as the AC inspection current to the detection signal generation unit. In addition, the voltage detection unit detects an AC voltage generated between the pair of probes in the supply state of the AC inspection current and outputs the AC voltage to the detector as a detection voltage signal. The detection signal generation unit generates a detection signal having the same frequency as that of an input reference signal and having a phase delayed by an arbitrary angle within an angle range exceeding 0° and less than 90° with respect to the reference signal, and outputs the detection signal to the detector. In this case, the detector receives the detection voltage signal and the detection signal, performs synchronous detection on the detection voltage signal with the detection signal, generates a DC detection voltage, and outputs the DC detection voltage to the processor.

In addition, the processor converts the DC detection voltage into voltage data, and calculates an impedance based on the voltage data and a known current value of the AC inspection current. Subsequently, the processor reads threshold value data stored in the storage and compares the threshold data with the calculated impedance. As a result of the comparison, when the calculated impedance exceeds a threshold value indicated by the threshold value data, the processor discriminates that the contact state is unsatisfactory because the contact resistance between the pair of electrodes of the secondary battery and the pair of probes is large, and when the calculated impedance is equal to or less than the threshold value, the processor discriminates that the contact state is satisfactory because the contact resistance is small. Subsequently, the processor outputs the determination result to the output unit. Thus, a user can accurately ascertain the contact state between the pair of electrodes of the secondary battery and the pair of probes based on the determination result displayed on the output unit.

### CITATION LIST

### Patent Literature

Patent Literature 1: JP 2007-171069 A (Pages 6 to 8, FIGS. 1 and 2)
Patent Literature 2: JP 6358920 B (Pages 7 to 14, FIG. 1)

### SUMMARY OF INVENTION

### Technical Problem

However, the insulation withstand voltage tester disclosed in Patent Literature 1 and the contact state determining device disclosed in Patent Literature 2 have the following problems to be solved. That is, in order to determine the contact state between the probes P1 and P2 for applying voltage and the object to be tested, the withstand voltage tester disclosed in Patent Literature 1 includes the power supply for detecting disconnection, the Hi-side disconnection voltage detection unit, and the Lo-side disconnection current detection unit, in addition to the power supply section (the withstand voltage test power supply and the insulation resistance test power supply). The contact state determining device disclosed in Patent Literature 2 requires a dedicated contact state determining device including the voltage detection unit, the detection signal generation unit, and the detector, separately from the inspection device, in order to discriminate the contact state between the pair of probes and the determination target portions (pair of electrodes) of the secondary battery as the inspection target. Therefore, in both of the devices disclosed in Patent Literatures 1 and 2, since the manufacturing cost increases and the circuit scale becomes large, miniaturization of the device as a whole is difficult, and this problem needs to be solved.

The present invention has been made to solve the problems described above, and a main object thereof is to provide an inspection device, a contact state determining device, and a contact state determining method capable of reducing the manufacturing cost of the device and miniaturizing the device.

### Solution to Problem

In order to accomplish the object described above, an inspection device according to the present invention is an inspection device including an inspection voltage generation unit configured to generate an inspection voltage, a pair of probes configured to supply the inspection voltage generated by the inspection voltage generation unit between a pair of determination target portions of an inspection target in a state where the pair of probes is brought into contact with the pair of determination target portions, the inspection target having capacitance between the pair of determination target portions, a current measurement unit configured to measure a current value of a current flowing between the pair of determination target portions in a state where the inspection voltage is supplied between the pair of determination target portions, and a processor configured to perform inspection processing of inspecting whether the inspection target is satisfactory or unsatisfactory based on the current value of the current flowing between the pair of determination target portions measured by the current measurement unit, and determination processing of determining whether a contact state between the pair of probes brought into contact with the pair of determination target portions, and the pair of determination target portions is satisfactory or unsatisfactory, the inspection device including: a storage configured to store a capacitance value of capacitance between the pair of probes in a non-contact state with the pair of determination target portions, and a threshold value set to a value equal to or less than the capacitance value of the capacitance between the pair of determination target portions; a discharge unit configured to perform discharge processing of discharging electric charge accumulated in the capacitance between the pair of probes; and a capacitance measurement unit configured to measure a capacitance value of capacitance between the pair of probes in a contact state with the pair of determination target portions, wherein the processor performs the determination processing after the inspection processing, causes the capacitance measurement unit to measure the capacitance value of the capacitance between the pair of probes in a contact state with the pair of determination target portions based on a discharge time of the electric charge in the discharge processing, and determines whether the contact state between the pair of probes and the pair of determination target portions is satisfactory or unsatisfactory based on whether a capacitance value obtained by subtracting the capacitance value of the capacitance between the pair of probes stored in the storage from the capacitance value measured by the capacitance measurement unit exceeds the threshold value stored in the storage.

In addition, a contact state determining device according to the present invention is a contact state determining device including a processor configured to perform determination processing of determining whether a contact state between a pair of probes brought into contact with a pair of determination target portions of an inspection target, and the pair of determination target portions is satisfactory or unsatisfactory, the inspection target having capacitance between the pair of determination target portions, the contact state determining device including: a storage configured to store a capacitance value of capacitance between the pair of probes in a non-contact state with the pair of determination target portions, and a threshold value set to a value equal to or less than a capacitance value of the capacitance between the pair of determination target portions; and a capacitance measurement unit configured to measure a capacitance value of capacitance between the pair of probes in a contact state with the pair of determination target portions, wherein in the determination processing, the processor determines whether the contact state between the pair of probes and the pair of determination target portions is satisfactory or unsatisfactory based on whether a capacitance value obtained by subtracting the capacitance value of the capacitance between the pair of probes stored in the storage from the capacitance value measured by the capacitance measurement unit exceeds the threshold value stored in the storage.

In addition, a contact state determining method according to the present invention is a contact state determining method for performing determination processing of determining whether a contact state between a pair of probes brought into contact with a pair of determination target portions of an inspection target, and the pair of determination target portions is satisfactory or unsatisfactory, the inspection target having capacitance between the pair of determination target portions, the contact state determining method including, in the determination processing, measuring a capacitance value of capacitance between the pair of probes in a contact state with the pair of determination target portions, and determining whether the contact state between the pair of probes and the pair of determination target portions is satisfactory or unsatisfactory based on whether a capacitance value obtained by subtracting a capacitance value of capacitance between the pair of probes in a non-contact state with the pair of determination target portions from the measured capacitance value exceeds a threshold value set to a value equal to or less than a capacitance value of the capacitance between the pair of determination target portions.

Accordingly, according to the inspection device, the contact state determining device, and the contact state determining method, the contact state can be determined only by using a simple configuration of the capacitance measurement unit that can measure the capacitance value of the capacitance between the pair of probes in a contact state with the pair of determination target portions, and the processor that compares the capacitance value obtained by subtracting the capacitance value of the capacitance between the pair of probes in a non-contact state with the pair of determination target portions from the measured capacitance value with the threshold value, thereby reducing the manufacturing cost of the device and reducing the size of the device. In addition, according to the inspection device, the capacitance value of the capacitance between the pair of probes can be measured using the configuration originally used for the inspection processing by the inspection device, and as a result, an increase in the manufacturing cost of the device and an increase in the size of the device can be avoided. The capacitance value of the capacitance between the pair of probes can be measured within the execution time of the discharge processing originally required after the inspection processing, and as a result, extension of the inspection time can be avoided.

In addition, in order to accomplish the object described above, an inspection device according to the present invention is an inspection device including an inspection voltage generation unit configured to generate an inspection voltage, a pair of probes configured to supply the inspection voltage generated by the inspection voltage generation unit between a pair of determination target portions of an inspection target in a state where the pair of probes is brought into contact with the pair of determination target portions, the inspection target having capacitance between the pair of determination target portions, a current measurement unit configured to measure a current value of a current flowing between the pair of determination target portions in a state where the inspection voltage is supplied between the pair of determination target portions, and a processor configured to perform inspection processing of inspecting whether the inspection target is satisfactory or unsatisfactory based on the current value of the current flowing between the pair of determination target portions measured by the current measurement unit, and determination processing of determining whether a contact state between the pair of probes brought into contact with the pair of determination target portions, and the pair of determination target portions is satisfactory or unsatisfactory, the inspection device including: a storage configured to store a threshold value set to a value equal to or less than a capacitance value of capacitance between the pair of probes in a contact state with the pair of determination target portions; a discharge unit configured to perform discharge processing of discharging electric charge accumulated in the capacitance between the pair of probes; and a capacitance measurement unit configured to measure a capacitance value of capacitance between the pair of probes in a contact state with the pair of determination target portions, wherein the processor performs the determination processing after the inspection processing, causes the capacitance measurement unit to measure the capacitance value of the capacitance between the pair of probes in a contact state with the pair of determination target portions based on a discharge time of the electric charge in the discharge processing, and determines whether the contact state between the pair of probes and the pair of determination target portions is satisfactory or unsatisfactory based on whether the capacitance value measured by the capacitance measurement unit exceeds the threshold value stored in the storage.

In addition, a contact state determining device according to the present invention is a contact state determining device including a processor configured to perform determination processing of determining whether a contact state between a pair of probes brought into contact with a pair of determination target portions of an inspection target, and the pair of determination target portions is satisfactory or unsatisfactory, the inspection target having capacitance between the pair of determination target portions, the contact state determining device including: a storage configured to store a threshold value set to a value equal to or less than a capacitance value of capacitance between the pair of probes in a contact state with the pair of determination target portions; and a capacitance measurement unit configured to measure a capacitance value of capacitance between the pair of probes in a contact state with the pair of determination target portions, wherein in the determination processing, the processor determines whether the contact state between the pair of probes and the pair of determination target portions is satisfactory or unsatisfactory based on whether the capacitance value measured by the capacitance measurement unit exceeds the threshold value stored in the storage.

In addition, a contact state determining method according to the present invention is a contact state determining method for performing determination processing of determining whether a contact state between a pair of probes brought into contact with a pair of determination target portions of an inspection target, and the pair of determination target portions is satisfactory or unsatisfactory, the inspection target having capacitance between the pair of determination target portions, the contact state determining method including, in the determination processing, measuring a capacitance value of capacitance between the pair of probes in a contact state with the pair of determination target portions, and determining whether the contact state between the pair of probes and the pair of determination target portions is satisfactory or unsatisfactory based on whether the measured capacitance value exceeds a threshold value set to a value equal to or less than the capacitance value of the capacitance between the pair of probes in a contact state with the pair of determination target portions.

Accordingly, according to the inspection device, the contact state determining device, and the contact state determining method, the contact state can be determined only by using a simple configuration of the capacitance measurement unit that can measure the capacitance value of the capacitance between the pair of probes in a contact state with the pair of determination target portions, and the processor that compares the measured capacitance value with the threshold value, thereby reducing the manufacturing cost of the device and reducing the size of the device. In addition, according to the inspection device, the capacitance value of the capacitance between the pair of probes can be measured using the configuration originally used for the inspection processing by the inspection device, and as a result, an increase in the manufacturing cost of the device and an increase in the size of the device can be avoided. The capacitance value of the capacitance between the pair of probes can be measured within the execution time of the discharge processing originally required after the inspection processing, and as a result, extension of the inspection time can be avoided.

In addition, in order to accomplish the object described above, an inspection device according to the present invention is an inspection device including an inspection voltage generation unit configured to generate an inspection voltage, a pair of probes configured to supply the inspection voltage generated by the inspection voltage generation unit between a pair of determination target portions of an inspection target in a state where the pair of probes is brought into contact with the pair of determination target portions, the inspection target having capacitance between the pair of determination target portions, a current measurement unit configured to measure a current value of a current flowing between the pair of determination target portions in a state where the inspection voltage is supplied between the pair of determination target portions, and a processor configured to perform inspection processing of inspecting whether the inspection target is satisfactory or unsatisfactory based on the current value of the current flowing between the pair of determination target portions measured by the current measurement unit, and determination processing of determining whether a contact state between the pair of probes brought into contact with the pair of determination target portions, and the pair of determination target portions is satisfactory or unsatisfactory, the inspection device including: a discharge unit configured to perform discharge processing of discharging electric charge accumulated in the capacitance between the pair of probes; a voltage measurement unit configured to be able to measure a voltage between the pair of probes during the discharge processing of discharging electric charge accumulated in the capacitance between the pair of probes in a contact state with the pair of determination target portions; and a storage configured to store a reference value for determining whether a contact state between the pair of probes is satisfactory or unsatisfactory by a comparison with a comparison value specified based on a voltage value of the voltage between the pair of probes measured by the voltage measurement unit, wherein the processor performs the determination processing after the inspection processing, specifies the comparison value based on the voltage value of the voltage measured by the voltage measurement unit during the discharge processing by the discharge unit, and determines whether the contact state between the pair of probes and the pair of determination target portions is satisfactory or unsatisfactory by comparing the comparison value specified with the reference value stored in the storage.

In addition, a contact state determining device according to the present invention is a contact state determining device including a processor configured to perform determination processing of determining whether a contact state between a pair of probes brought into contact with a pair of determination target portions of an inspection target, and the pair of determination target portions is satisfactory or unsatisfactory, the inspection target having capacitance between the pair of determination target portions, the contact state determining device including: a voltage measurement unit configured to measure a voltage between the pair of probes during discharge processing of discharging electric charge accumulated in capacitance between the pair of probes in a contact state with the pair of determination target portions; and a storage configured to store a reference value for determining whether a contact state between the pair of probes is satisfactory or unsatisfactory by a comparison with a comparison value specified based on a voltage value of the voltage between the pair of probes measured by the voltage measurement unit, wherein in the determination processing, the processor specifies the comparison value based on the voltage value of the voltage measured by the voltage measurement unit during the discharge processing, and determines whether the contact state between the pair of probes and the pair of determination target portions is satisfactory or unsatisfactory by comparing the comparison value specified with the reference value stored in the storage.

In addition, a contact state determining method according to the present invention is a contact state determining method for performing determination processing of determining whether a contact state between a pair of probes brought into contact with a pair of determination target portions of an inspection target, and the pair of determination target portions is satisfactory or unsatisfactory, the inspection target having capacitance between the pair of determination target portions, the contact state determining method including, in the determination processing, measuring a voltage between the pair of probes during discharge processing of discharging electric charge accumulated in capacitance between the pair of probes in a contact state with the pair of determination target portions, specifying a comparison value based on a voltage value of the voltage measured, and determining whether the contact state between the pair of probes and the pair of determination target portions is satisfactory or unsatisfactory by comparing a reference value with the comparison value specified, the reference value being used for determining whether a contact state between the pair of probes is satisfactory or unsatisfactory by a comparison with the comparison value.

Specifically, in the inspection device according to the present invention and the contact state determining device according to the present invention, the storage stores a first time and a second time as the reference value, the first time being a discharge time when electric charge accumulated between the pair of probes in a non-contact state with the pair of determination target portions is discharged under the same discharge condition as the discharge processing, the second time being set equal to or less than a discharge time when electric charge accumulated between the pair of determination target portions is discharged under the same discharge condition as the discharge processing, and in the determination processing, the processor specifies a third time as the comparison value, the third time being a discharge time of the electric charge accumulated between the pair of probes in a contact state with the pair of determination target portions, based on the voltage value of the voltage measured by the voltage measurement unit, and determines whether the contact state between the pair of probes and the pair of determination target portions is satisfactory or unsatisfactory by comparing a fourth time obtained by subtracting the first time from the third time specified with the second time.

In addition, in the inspection device according to the present invention and the contact state determining device according to the present invention, the storage stores a time A as the reference value, the time A being set equal to or less than a discharge time when the electric charge accumulated between the pair of probes in a contact state with the pair of determination target portions is discharged under the same discharge condition as the discharge processing, and in the determination processing, the processor specifies a time B as the comparison value, the time B being a discharge time of the electric charge accumulated between the pair of probes in a contact state with the pair of determination target portions, based on the voltage value of the voltage measured by the voltage measurement unit, and determines whether the contact state between the pair of probes and the pair of determination target portions is satisfactory or unsatisfactory by comparing the time B specified with the time A.

In addition, in the inspection device according to the present invention and the contact state determining device according to the present invention, the storage stores a first drop rate and a second drop rate as the reference value, the first drop rate being a drop rate of the voltage between the pair of probes when electric charge accumulated between the pair of probes in a non-contact state with the pair of determination target portions is discharged under the same discharge condition as the discharge processing, the second drop rate being set equal to or less than a drop rate of a voltage between the pair of determination target portions when electric charge accumulated between the pair of determination target portions is discharged under the same discharge condition as the discharge processing, and in the determination processing, the processor specifies a third drop rate, as the comparison value, the third drop rate being a drop rate of the voltage between the pair of probes during the discharge processing on the electric charge accumulated between the pair of probes in a contact state with the pair of determination target portions, based on the voltage value of the voltage measured by the voltage measurement unit, and determines whether the contact state between the pair of probes and the pair of determination target portions is satisfactory or unsatisfactory by comparing a fourth drop rate obtained by subtracting the first drop rate from the third drop rate specified with the second drop rate.

In addition, in the inspection device according to the present invention and the contact state determining device according to the present invention, the storage stores a drop rate A as the reference value, the drop rate A being set equal to or more than a drop rate of the voltage between the pair of probes when the electric charge accumulated between the pair of probes in a contact state with the pair of determination target portions is discharged under the same discharge condition as the discharge processing, and in the determination processing, the processor specifies a drop rate B as the comparison value, the drop rate B being a drop rate of the voltage between the pair of probes during the discharge processing om the electric charge accumulated between the pair of probes in a contact state with the pair of determination target portions, based on the voltage value of the voltage measured by the voltage measurement unit, and determines whether the contact state between the pair of probes and the pair of determination target portions is satisfactory or unsatisfactory by comparing the drop rate B specified with the drop rate A.

In addition, in the inspection device according to the present invention and the contact state determining device according to the present invention, the storage stores a first voltage value and a second voltage value as the reference value, the first voltage value being a voltage value of the voltage between the pair of probes at a time point when a predetermined time has elapsed from a discharge start when electric charge accumulated between the pair of probes in a non-contact state with the pair of determination target portions is discharged under the same discharge condition as the discharge processing, the second voltage value being set equal to or less than a voltage value of a voltage between the pair of determination target portions at a time point when the predetermined time has elapsed from a discharge start when electric charge accumulated between the pair of determination target portions is discharged under the same discharge condition as the discharge processing, and in the determination processing, the processor specifies a third voltage value as the comparison value, the third voltage value being a voltage value of the voltage between the pair of probes at a time point when the predetermined time has elapsed from a start of the discharge processing in the discharge processing on electric charge accumulated between the pair of probes in a contact state with the pair of determination target portions, based on the voltage value of the voltage measured by the voltage measurement unit, and determines whether the contact state between the pair of probes and the pair of determination target portions is satisfactory or unsatisfactory by comparing a fourth voltage value obtained by subtracting the first voltage value from the third voltage value specified with the second voltage value.

In addition, in the inspection device according to the present invention and the contact state determining device according to the present invention, the storage stores a voltage value A as the reference value, the voltage value A being set equal to or less than a voltage value of the voltage between the pair of probes at a time point when a predetermined time has elapsed from a discharge start when electric charge accumulated between the pair of probes in a contact state with the pair of determination target portions is discharged under the same discharge condition as the discharge processing, and in the determination processing, the processor specifies a voltage value B as the comparison value, the voltage value B being a voltage value of the voltage between the pair of probes at a time point when the predetermined time has elapsed from a start of the discharge processing in the discharge processing on electric charge accumulated between the pair of probes in a contact state with the pair of determination target portions, based on the voltage value of the voltage measured by the voltage measurement unit, and determines whether the contact state between the pair of probes and the pair of determination target portions is satisfactory or unsatisfactory by comparing the voltage value B specified with the voltage value A.

Therefore, according to the inspection device, the contact state determining device, and the contact state determining method, the contact state can be determined only by using a simple configuration of the voltage measurement unit that can measure the voltage between the pair of probes during the discharge processing of discharging the electric charge accumulated in the capacitance between the pair of probes in a contact state with the pair of determination target portions, and the processor that specifies the comparison value based on the measured voltage value and compares the specified comparison value with the reference value stored in the storage, thereby reducing the manufacturing cost of the device and reducing the size of the device. In addition, according to the inspection device, the capacitance value of the capacitance between the pair of probes can be measured using the configuration originally used for the inspection processing by the inspection device, and as a result, an increase in the manufacturing cost of the device and an increase in the size of the device can be avoided. The capacitance value of the capacitance between the pair of probes can be measured within the execution time of the discharge processing originally required after the inspection processing, and as a result, extension of the inspection time can be avoided.

### Advantageous Effects of Invention

In accordance with the inspection device, the contact state determining device, and the contact state determining method according to the present invention, the contact state can be determined only by using a simple configuration of the capacitance measurement unit that can measure the capacitance value of the capacitance between the pair of probes in a contact state with the pair of determination target portions and the processor that compares the measured capacitance value with the threshold value, or a simple configuration of the voltage measurement unit that can measure the voltage between the pair of probes during the discharge processing of discharging the electric charge accumulated in the capacitance between the pair of probes in a contact state with the pair of determination target portions and the processor that specifies the comparison value based on the measured voltage value and compares the specified comparison value with the reference value stored in the storage, thereby reducing the manufacturing cost of the device and reducing the size of the device.

### BRIEF DESCRIPTION OF DRAWINGS

FIG. 1 is a configuration diagram of an insulation resistance measurement device 1 (1A and 1B) and a secondary battery DUT.

FIG. 2 is an explanatory diagram for explaining a method of measuring the capacitance value of capacitance between probes P1 and P2 in a non-contact state with a positive electrode terminal Tp and a metal layer Lm.

FIG. 3 is an explanatory diagram for explaining a method of measuring the capacitance value of capacitance between the probes P1 and P2 in a contact state with the positive electrode terminal Tp and the metal layer Lm.

### DESCRIPTION OF EMBODIMENTS

Embodiments of an inspection device, a contact state determining device, and a contact state determining method are described with reference to the accompanying drawings.

### First Example

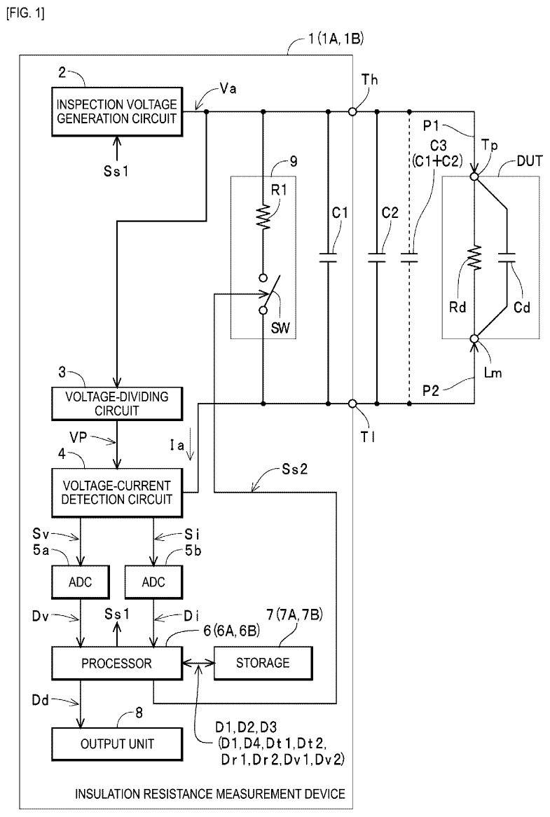

An insulation resistance measurement device 1 illustrated in FIG. 1 is an example of an inspection device also referred to as an insulation test device having a contact state determining device, and is configured to be able to measure insulation resistance between a pair of inspection target portions of an inspection target. Hereinafter, for example, an example in which a secondary battery DUT is set as an inspection target and a positive electrode terminal Tp and a metal layer Lm of the secondary battery DUT are set as a pair of inspection target portions (determination target portions) is described.

First, configurations of the insulation resistance measurement device 1 and the secondary battery DUT are described with reference to FIG. 1.

The insulation resistance measurement device 1 includes an inspection voltage generation circuit 2, a voltage-dividing circuit 3, a voltage-current detection circuit 4, A/D converters 5a and 5b (denoted as “ADC” in FIG. 1), a processor 6, a storage 7, an output unit 8, a discharge circuit 9, and probes P1 and P2.

The inspection voltage generation circuit 2 functions as an inspection voltage generation unit, and in accordance with a control signal Ss1 output from the processor 6, receives commercial power (not illustrated), converts the commercial power into a DC voltage, generates a pulse voltage, boosts the pulse voltage to generate a high-voltage pulse voltage, and then rectifies the high-voltage pulse voltage to generate and output an inspection DC voltage Va. The voltage-dividing circuit 3 outputs a divided voltage Vp obtained by dividing the inspection DC voltage Va output from the inspection voltage generation circuit 2 at a predetermined voltage dividing ratio.

The voltage-current detection circuit 4 receives the divided voltage Vp output from the voltage-dividing circuit 3, amplifies the divided voltage Vp with a predetermined gain, converts the amplified voltage into a voltage signal Sv indicating the voltage value of the inspection DC voltage Va, and outputs the voltage signal Sv. In addition, the voltage-current detection circuit 4 functions as a current measurement unit, and as described below, when the inspection DC voltage Va is applied between the positive electrode terminal Tp and the metal layer Lm of the secondary battery DUT, receives a current Ia flowing between the positive electrode terminal Tp and the metal layer Lm, converts the current Ia into a current signal Si indicating a current value of the current Ia, and outputs the current signal Si.

The A/D converter 5a receives the voltage signal Sv output from the voltage-current detection circuit 4 and performs AC/DC conversion to generate and output voltage value data Dv indicating a voltage value of the voltage signal Sv. In addition, the A/D converter 5b receives the current signal Si output from the voltage-current detection circuit 4 and performs AC/DC conversion to generate and output current value data Di indicating a current value of the current signal Si.

The processor 6 receives the voltage value data Dv outputted from the A/D converter 5a to calculate the voltage value of the inspection DC voltage Va, and receives the current value data Di outputted from the A/D converter 5b to calculate the current value of the current Ia. In addition, the processor 6 calculates a resistance value of an insulation resistor Rd to be described below between the positive electrode terminal Tp and the metal layer Lm of the secondary battery DUT based on the calculated voltage value of the DC voltage Va and the calculated current value of the current Ia, and performs an inspection processing (insulation inspection processing) of inspecting whether the insulating property between the positive electrode terminal Tp and the metal layer Lm of the secondary battery DUT is satisfactory or unsatisfactory based on the calculated resistance value. In addition, the processor 6 performs determination processing of determining whether a contact state between the pair of probes P1 and P2, which are brought into contact with the positive electrode terminal Tp and the metal layer Lm that are the pair of determination target portions in the secondary battery DUT, and the positive electrode terminal Tp and the metal layer Lm is satisfactory or unsatisfactory. In addition, the processor 6 outputs the control signal Ss1 to control the inspection voltage generation circuit 2 to start and stop outputting the inspection DC voltage Va. In addition, the processor 6 outputs a control signal Ss2 to control the start and stop of discharge by the discharge circuit 9. In addition, the processor 6 also functions as a capacitance measurement unit and measures capacitance values of capacitance C3 and capacitance Cd to be described below.

In addition, by outputting display data Dd to the output unit 8, the processor 6 displays the resistance value of the insulation resistor Rd between the positive electrode terminal Tp and the metal layer Lm of the secondary battery DUT, the inspection result regarding whether the insulating property between the positive electrode terminal Tp and the metal layer Lm of the secondary battery DUT is satisfactory or unsatisfactory, and the determination result regarding whether the contact state between the probes P1 and P2 and the positive electrode terminal Tp and the metal layer Lm is satisfactory or unsatisfactory.

The storage 7 includes, for example, a semiconductor memory, a hard disk device, or the like. The storage 7 also stores an operation program for the processor 6, first data D1 indicating a threshold value being a reference value of an insulation resistance value used in the inspection processing by the processor 6, second data D2 indicating a known capacitance value of the capacitance C3 to be described below between the pair of probes P1 and P2 in a non-contact state with the positive electrode terminal Tp and the metal layer Lm that are the pair of determination target portions (inspection target portions) used in the determination processing by the processor 6, and third data D3 indicating a threshold value set to a value equal to or less than a known capacitance value of the capacitance Cd to be described below between the positive electrode terminal Tp and the metal layer Lm used in the determination processing by the processor 6.

The output unit 8 includes a display device such as a display, receives the display data Dd from the processor 6, and displays the measured value of the insulation resistor Rd between the positive electrode terminal Tp and the metal layer Lm of the secondary battery DUT, the inspection result regarding whether the insulating property of the secondary battery DUT is satisfactory or unsatisfactory, the determination result regarding whether the contact state between the probes P1 and P2 and the positive electrode terminal Tp and the metal layer Lm is satisfactory or unsatisfactory, or the like. Note that the output unit 8 can also include an external interface circuit instead of the display device. In this configuration, the output unit 8 outputs the results of the above processes to an external device via the external interface circuit.

The discharge circuit 9 is an example of “a discharge unit that performs a discharge processing of discharging electric charge accumulated in the capacitance between the pair of probes”, includes a series circuit of a discharge resistor R1 and a switch SW, and is disposed between a high-voltage-side terminal Th and a low-voltage-side terminal Tl to be described below. In this case, in the discharge circuit 9, when the control signal Ss2 is output from the processor 6 and the discharge processing is performed, the switch SW is controlled to be in an ON state, and the discharge resistor R1 is connected between the high-voltage-side terminal Th and the low-voltage-side terminal Tl. Therefore, in the discharge processing, the discharge circuit 9 discharges the electric charge accumulated in the capacitance (the capacitance C3 and the capacitance Cd of the secondary battery DUT to be described below) between the high-voltage-side terminal Th and the low-voltage-side terminal Tl (between the probes P1 and P2) through the discharge resistor R1.

The probe P1 is connected to the high-voltage-side terminal Th for inspection provided on a housing of the insulation resistance measurement device 1, and the probe P2 is connected to the low-voltage-side terminal Tl for inspection provided on the housing of the insulation resistance measurement device 1.

As illustrated in FIG. 1, in the insulation resistance measurement device 1, internal capacitance C1 of the insulation resistance measurement device 1 is equivalently present between the high-voltage-side terminal Th and the low-voltage-side terminal Tl. In addition, wiring capacitance C2 is equivalently present between the pair of probes P1 and P2 connected to the pair of high-voltage-side terminal Th and low-voltage-side terminal Tl. Hereinafter, capacitance obtained by adding the internal capacitance C1 and the wiring capacitance C2 is referred to as the “capacitance C3” described above.

In addition, the contact state determining device is configured by a part (the inspection voltage generation circuit 2, the voltage-dividing circuit 3, the voltage-current detection circuit 4, the A/D converter 5a, the processor 6, the storage 7, and the discharge circuit 9) of the components of the above insulation resistance measurement device 1.

The configuration of the secondary battery DUT being an inspection target is described below. FIG. 1 schematically illustrates the configuration of the secondary battery DUT. In this case, the secondary battery DUT includes, for example, an exterior member, an electrode group, an electrolyte, and a pair of electrodes (the positive electrode terminal Tp illustrated in the drawing and a negative electrode terminal not illustrated). In this case, the exterior member is configured by molding a laminate film, in which a synthetic resin layer (for example, polyethylene) is bonded to both surfaces of the metal layer (sealant) Lm, into a bag shape or a cup shape, and the electrode group and the electrolyte are housed in the exterior member. The positive electrode terminal Tp is connected to a positive electrode of the electrode group, and the negative electrode terminal is connected to a negative electrode of the electrode group. In the drawing, the insulation resistor between the positive electrode terminal Tp and the metal layer Lm is shown as an insulation resistor Rd.

The operation of the insulation resistance measurement device 1 is described below together with the contact state determining method.

First, a method of preparing the first data D1, the second data D2, and the third data D3 to be stored in the storage 7 is described. As described above, the first data D1 is the threshold value being the reference value of the insulation resistance value used in the inspection processing (insulation inspection) by the processor 6, and the lower limit resistance value of the insulation resistor Rd required for the secondary battery DUT as a satisfactory product is stored in advance in the storage 7. As described above, the second data D2 indicates the capacitance value of the capacitance C3 between the probes P1 and P2 in a non-contact state with the positive electrode terminal Tp and the metal layer Lm used in the determination processing by the processor 6, and the capacitance value of the capacitance C3 between the probes P1 and P2 measured in advance as described below is stored in advance in the storage 7. The third data D3 is a threshold value used in the determination processing by the processor 6, and is set to a value equal to or less than the known capacitance value of the capacitance Cd between the positive electrode terminal Tp and the metal layer Lm (for example, a value of 80% of the known capacitance value of the capacitance Cd) and stored in advance in the storage 7.

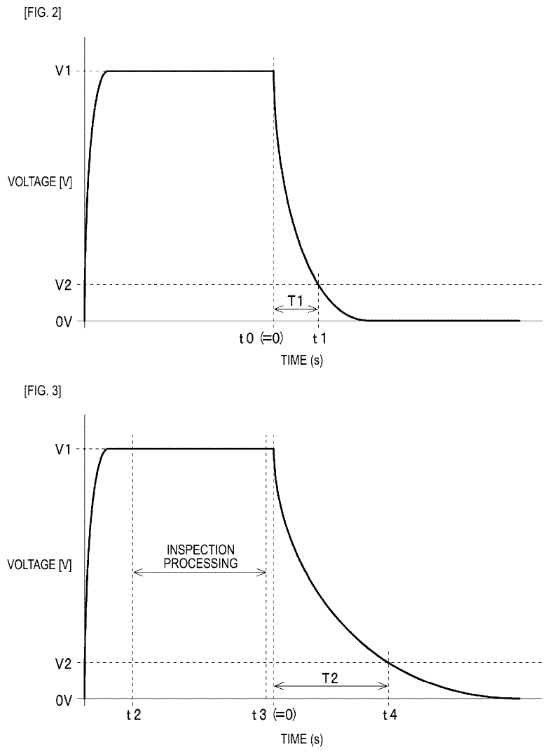

An example of a measurement method for measuring the capacitance value of the capacitance C3 between the probes P1 and P2 in a non-contact state with the positive electrode terminal Tp and the metal layer Lm is described below with reference to FIG. 2. First, base end portions of the probes P1 and P2 are connected to the high-voltage-side terminal Th and the low-voltage-side terminal Tl, and tip end portions of the probes P1 and P2 are maintained in an open state in which the tip end portions are not connected to the secondary battery DUT. In this state, an operation unit (not illustrated) is operated to cause the processor 6 to output the control signal Ss1 to the inspection voltage generation circuit 2, thereby causing the inspection voltage generation circuit 2 to output the inspection DC voltage Va having a predetermined voltage value V1 (for example, DC 500V). In this case, the inspection DC voltage Va charges the capacitance C3 described above, so that the voltage across the capacitance C3 increases toward the predetermined voltage value V1. At this time, the voltage-current detection circuit 4 outputs the voltage signal Sv to the A/D converter 5a based on the divided voltage Vp output from the voltage-dividing circuit 3. Subsequently, the A/D converter 5a generates the voltage value data Dv based on the voltage signal Sv and outputs the voltage value data Dv to the processor 6.

Subsequently, the processor 6 performs the discharge processing at a time to after the inspection DC voltage Va reaches the predetermined voltage value V1. At this time, the processor 6 stops outputting the control signal Ss1 to the inspection voltage generation circuit 2 to stop outputting the inspection DC voltage Va, outputs the control signal Ss2 to the discharge circuit 9, and starts measuring time with an internal timer. At this time, in the discharge circuit 9, since the switch SW is controlled to be in an ON state in accordance with the control signal Ss2, the discharge resistor R1 is connected between the high-voltage-side terminal Th and the low-voltage-side terminal Tl. As a result, the discharge resistor R1 gradually discharges the electric charge accumulated in the capacitance C3 between the probes P1 and P2. Subsequently, the processor 6 monitors the voltage value of the voltage across the capacitance C3 (the voltage between the high-voltage-side terminal Th and the low-voltage-side terminal Tl: the voltage between the probes P1 and P2) indicated by the voltage value data Dv, and obtains the measurement value of the internal timer until the voltage across the capacitance C3 gradually decreases as the electric charge accumulated in the capacitance C3 decreases and reaches a predetermined voltage value V2 (for example, 30 V) at a time t1. That is, the processor 6 measures a time T1 (time from the time point to to the time point t1: s for the unit of time) required for the voltage across the capacitance C3 to drop from the voltage value V1 to the voltage value V2 by short-circuiting both ends of the capacitance C3 with the discharge resistor R1. Subsequently, the processor 6 measures a capacitance value Vcs of the capacitance C3 in accordance with a calculation formula represented by the following Equation (1). Subsequently, the processor 6 stores the measured capacitance value Vcs of the capacitance C3 in the storage 7 as the above second data D2. In this equation and the following equation (2) to be described below, V_{R1} means the resistance value of the discharge resistor R1.

V_{C3}=−(1/logₑ(V2/V1))×T1/V_{R1} Equation (1)

An example of an inspection processing for the secondary battery DUT is described below.

In this inspection processing, first, the base end portion of the probe P1 is connected to the high-voltage-side terminal Th, and the base end portion of the probe P2 is connected to the low-voltage-side terminal Tl. The tip end portion of the probe P1 is connected to the positive electrode terminal Tp of the secondary battery DUT, and the tip end portion of the probe P2 is connected to the metal layer Lm of the secondary battery DUT. In this state, the processor 6 measures the resistance value of the insulation resistor Rd based on the current value of the current Ia flowing between the pair of determination target portions (between the positive electrode terminal Tp and the metal layer Lm) measured by the voltage-current detection circuit 4, and inspects whether the insulation property of the secondary battery DUT is satisfactory or unsatisfactory based on the measured resistance value.

Specifically, an operation unit (not illustrated) is operated to instruct the processor 6 to start the inspection processing. At this time, the processor 6 outputs the control signal Ss1 to the inspection voltage generation circuit 2, thereby causing the inspection voltage generation circuit 2 to output the inspection DC voltage Va having the predetermined voltage value V1. In this case, the inspection DC voltage Va charges the capacitance C3 and the capacitance Cd of the secondary battery DUT, so that the voltage between the high-voltage-side terminal Th and the low-voltage-side terminal Tl increases toward the predetermined voltage value V1. At this time, the voltage-current detection circuit 4 outputs the voltage signal Sv to the A/D converter 5a based on the divided voltage Vp output from the voltage-dividing circuit 3. Subsequently, the A/D converter 5a generates the voltage value data Dv based on the voltage signal Sv and outputs the voltage value data Dv to the processor 6. The voltage-current detection circuit 4 detects the current value of the current Ia flowing through a current path including the inspection voltage generation circuit 2, the high-voltage-side terminal Th, the probe P1, the positive electrode terminal Tp of the secondary battery DUT, the metal layer Lm of the secondary battery DUT, the probe P2, the low-voltage-side terminal Tl, and the voltage-current detection circuit 4, and outputs the current signal S1 to the A/D converter 5b. Subsequently, the A/D converter 5b generates the current value data Di based on the current signal Si, and outputs the current value data Di to the processor 6.

Subsequently, the processor 6 starts a resistance value measurement processing of measuring the resistance value of the insulation resistor Rd at a time t2 after the voltage value of the input voltage value data Dv reaches the predetermined voltage value V1. In the resistance value measurement processing, the processor 6 measures the resistance value of the insulation resistor Rd between the positive electrode terminal Tp and the metal layer Lm of the secondary battery DUT based on the voltage value of the input voltage value data Dv and the current value of the input current value data Di. Subsequently, the processor 6 compares the measured resistance value with the threshold value indicated by the first data D1 stored in the storage 7, determines that the insulation of the secondary battery DUT is satisfactory when the measured resistance value exceeds the threshold value, and determines that the insulation of the secondary battery DUT is unsatisfactory when the measured resistance value is equal to or less than the threshold value. Thus, the inspection processing by the processor 6 is ended.

Subsequently, the processor 6 performs the discharge processing at a time t3 after the inspection processing is ended in a state where the inspection DC voltage Va is maintained at the predetermined voltage value V1. In this discharge processing, the processor 6 outputs the control signal Ss2 to the discharge circuit 9 to discharge the electric charge accumulated in the capacitance C3 between the probes P1 and P2 and the capacitance Cd via the discharge resistor R1 in the same manner as in the above discharge processing. In addition, the processor 6 measures the capacitance value of the capacitance Cd during the execution of the discharge processing.

Specifically, similarly to the measurement of the capacitance value of the capacitance C3 described above, the processor 6 stops outputting the control signal Ss1 to the inspection voltage generation circuit 2 to stop outputting the inspection DC voltage Va, outputs the control signal Ss2 to the discharge circuit 9, and starts measuring the time with the internal timer. At this time, in the discharge circuit 9, since the switch SW is controlled to be in an ON state in accordance with the control signal Ss2, the discharge resistor R1 is connected between the high-voltage-side terminal Th and the low-voltage-side terminal Tl. As a result, the discharge resistor R1 gradually discharges the electric charge accumulated in the capacitance C3 between the probes P1 and P2 and the capacitance Cd. Subsequently, the processor 6 monitors the voltage value of the voltage between the high-voltage-side terminal Th and the low-voltage-side terminal Tl (also the voltage between the probes P1 and P2) indicated by the voltage value data Dv, and obtains a measurement value of the internal timer up to a time point t4 at which the voltage between the high-voltage-side terminal Th and the low-voltage-side terminal Tl gradually decreases as the electric charge accumulated in the capacitance C3 and the capacitance Cd decreases and reaches the predetermined voltage value V2 (for example, 30 V). That is, the processor 6 measures a time T2 (time from the time point t3 to the time point t4: s for the unit of time) required for the voltage across the capacitance C3 (also the capacitance Cd) to drop from the voltage value V1 of the inspection DC voltage Va to the voltage value V2 by short-circuiting the high-voltage-side terminal Th and the low-voltage-side terminal Tl with the discharge resistor R1, and measures the capacitance value of capacitance obtained by adding the capacitance C3 and the capacitance Cd according to a calculation formula indicated by a first term on the right side of the following Equation (2). Subsequently, the processor 6 measures a capacitance value V_{Cd} of the capacitance Cd by subtracting the capacitance value Vcs of the capacitance C3 stored in the storage 7 from the measured capacitance value of the capacitance obtained by adding the capacitance C3 and the capacitance Cd in accordance with Equation (2). Subsequently, the processor 6 stores the measured capacitance value V_{Cd} of the capacitance Cd in the storage 7.

$${V}_{Cd} = - ( 1 / {log}_{e} ( V 2 / V 1 ) ) \times T 2 / {V}_{R 1} - {V}_{C 3} \qquad ( 2 )$$

Subsequently, the processor 6 compares the measured capacitance value V_{Cd} of the capacitance Cd with the threshold value indicated by the third data D3 stored in the storage 7. In this case, in at least one of when the contact between the probe P1 and the positive electrode terminal Tp is unsatisfactory and the contact resistance is high and when the contact between the probe P2 and the metal layer Lm is unsatisfactory and the contact resistance is high, since the capacitance value V_{Cd} of the capacitance Cd is measured to be small when the capacitance value of the capacitance obtained by adding the capacitance C3 and the capacitance Cd is measured, the capacitance value V_{Cd} of the capacitance Cd measured by Equation (2) above is small. Accordingly, the processor 6 determines that the contact between the probes P1 and P2 and the positive electrode terminal Tp and the metal layer Lm is satisfactory when the measured capacitance value V_{Cd} exceeds the threshold value, and determines that the contact between the probes P1 and P2 and the positive electrode terminal Tp and the metal layer Lm is unsatisfactory when the measured capacitance value V_{Cd} is equal to or less than the threshold value.

Subsequently, the processor 6 performs an output processing. At this time, when the processor 6 determines that the result of the insulation inspection is satisfactory and determines that the contact state is satisfactory, the processor 6 puts the measured resistance value of the insulation resistor Rd, the result of the insulation inspection, and the determination result of the contact state of the probes P1 and P2 into the display data Dd, and outputs the display data Dd to the output unit 8. Thus, the output unit 8 displays the resistance value of the insulation resistor Rd, the result of the insulation inspection, and the determination result of the contact state of the probes P1 and P2. On the other hand, when the processor 6 determines that the contact state is unsatisfactory, the processor 6 puts this determination result into the display data Dd and outputs the display data Dd to the output unit 8. Thus, the output unit 8 displays the fact that the contact state of the probes P1 and P2 is unsatisfactory and that the probes P1 and P2 are preferably contacted again. As above, the insulation inspection by the insulation resistance measurement device 1 is ended. As a result, a user of the insulation resistance measurement device 1 can ascertain the quality of the secondary battery DUT based on the result of the insulation inspection displayed on the output unit 8.

In this way, in the insulation resistance measurement device 1, the contact state determining device, and the contact state determining method, in the determination processing of determining whether a contact state between the probes P1 and P2 (a pair of probes), which are brought into contact with the positive electrode terminal Tp and the metal layer Lm (a pair of determination target portions) in the secondary battery DUT having the capacitance Cd between the positive electrode terminal Tp and the metal layer Lm, and the positive electrode terminal Tp and the metal layer Lm is satisfactory or unsatisfactory, when the capacitance value of the capacitance (capacitance obtained by adding the capacitance C3 and the capacitance Cd) between the probes P1 and P2 in a contact state with the positive electrode terminal Tp and the metal layer Lm is measured and a capacitance value obtained by subtracting the capacitance value Vcs of the capacitance C3 between the probes P1 and P2 in a non-contact state with the positive electrode terminal Tp and the metal layer Lm from the measured capacitance value exceeds the threshold value (third data D3) set to a value equal to or less than the capacitance value V_{Cd} of the capacitance Cd between the positive electrode terminal Tp and the metal layer Lm, the contact state between the probes P1 and P2 and the positive electrode terminal Tp and the metal layer Lm is determined to be satisfactory.

Accordingly, according to the insulation resistance measurement device 1, the contact state determining device, and the contact state determining method, the contact state can be determined only by using a simple configuration of the capacitance measurement unit (the processor 6 in this example) that can measure the capacitance value of the capacitance (capacitance obtained by adding the capacitance C3 and the capacitance Cd) between the probes P1 and P2 in a contact state with the positive electrode terminal Tp and the metal layer Lm and the processor (the processor 6 in this example) that compares the capacitance value obtained by subtracting the capacitance value of the capacitance C3 between the probes P1 and P2 in a non-contact state with the positive electrode terminal Tp and the metal layer Lm from the measured capacitance value with the threshold value, thereby reducing the manufacturing cost of the device and reducing the size of the device.

In addition, in the insulation resistance measurement device 1, the switch SW is controlled to an ON state to perform the discharge processing of discharging the electric charge accumulated in the capacitance (the capacitance C3 and the capacitance Cd) between the probes P1 and P2 via the insulation resistor Rd, and the capacitance value of the capacitance between the probes P1 and P2 in a contact state with the positive electrode terminal Tp and the metal layer Lm is measured based on the discharge time of the electric charge in the discharge processing.

Accordingly, according to the insulation resistance measurement device 1, the capacitance value of the capacitance between the probes P1 and P2 can be measured using the configuration originally used for the inspection processing by the insulation resistance measurement device 1, and as a result, an increase in the manufacturing cost of the device and an increase in the size of the device can be avoided.

In addition, according to the insulation resistance measurement device 1, by performing the discharge processing after the inspection processing, the capacitance value of the capacitance between the probes P1 and P2 can be measured within the execution time of the discharge processing originally required after the inspection processing, and as a result, extension of the inspection time can be avoided.

### Second Example

A configuration of an insulation resistance measurement device 1A is described below with reference to the drawing.

The insulation resistance measurement device 1A illustrated in FIG. 1 is another example of an inspection device having a contact state determining device, and measures insulation resistance between a pair of inspection target portions of an inspection target. Hereinafter, for example, an example in which a secondary battery DUT is set as an inspection target and a positive electrode terminal Tp and a metal layer Lm of the secondary battery DUT are set as a pair of inspection target portions (determination target portions) is described. Note that the same components and functions as those of the insulation resistance measurement device 1 are denoted by the same reference numerals, and redundant description thereof is omitted.

The insulation resistance measurement device 1A includes an inspection voltage generation circuit 2, a voltage-dividing circuit 3, a voltage-current detection circuit 4, A/D converters 5a and 5b, a processor 6A, a storage 7A, an output unit 8, a discharge circuit 9, and probes P1 and P2. In addition, a contact state determining device is configured by a part (the inspection voltage generation circuit 2, the voltage-dividing circuit 3, the voltage-current detection circuit 4, the A/D converter 5a, the processor 6A, the storage 7A, and the discharge circuit 9) of the components of the above insulation resistance measurement device 1A.

Unlike the processor 6, in the determination processing of determining whether a contact state between the probes P1 and P2 (a pair of probes), which are brought into contact with the positive electrode terminal Tp and the metal layer Lm (a pair of determination target portions) in the secondary battery DUT having the capacitance Cd between the positive electrode terminal Tp and the metal layer Lm, and the positive electrode terminal Tp and the metal layer Lm is satisfactory or unsatisfactory, the processor 6A of the insulation resistance measurement device 1A measures the capacitance value of capacitance (capacitance obtained by adding the capacitance C3 and the capacitance Cd) between the probes P1 and P2 in a contact state with the positive electrode terminal Tp and the metal layer Lm, and determines that the contact state between the probes P1 and P2 and the positive electrode terminal Tp and the metal layer Lm is satisfactory when the measured capacitance value exceeds a threshold value (fourth data Dt4 to be described below) set to a value equal to or less than a capacitance value of the capacitance between the probes P1 and P2 in a satisfactory contact state with the positive electrode terminal Tp and the metal layer Lm.

In this case, similarly to the processor 6 of the above insulation resistance measurement device 1, in at least one of when the contact between the probe P1 and the positive electrode terminal Tp is unsatisfactory and the contact resistance is high and when the contact between the probe P2 and the metal layer Lm is unsatisfactory and the contact resistance is high, since the capacitance value V_{Cd} of the capacitance Cd is measured to be small when the capacitance value of the capacitance obtained by adding the capacitance C3 and the capacitance Cd is measured, the capacitance value V_{Cd} of the capacitance Cd measured by Equation (2) above is small. Accordingly, the processor 6A determines that the contact between the probes P1 and P2 and the positive electrode terminal Tp and the metal layer Lm is satisfactory when the measured capacitance value exceeds the threshold value, and determines that the contact between the probes P1 and P2 and the positive electrode terminal Tp and the metal layer Lm is unsatisfactory when the measured capacitance value is equal to or less than the threshold value.

The storage 7A stores the first data D1 described above and, unlike the storage 7, stores fourth data D4 indicating a threshold set to a value equal to or less than a known capacitance value (for example, a value of 80% of the known capacitance value) of the capacitance (capacitance obtained by adding the capacitance C3 and the capacitance Cd) between the probes P1 and P2 in satisfactory contact with the positive electrode terminal Tp and the metal layer Lm that are a pair of inspection target portions (determination target portions) used in the determination processing by the processor 6A. The capacitance (capacitance obtained by adding the capacitance C3 and the capacitance Cd) between the probes P1 and P2 in a satisfactory contact state with the positive electrode terminal Tp and the metal layer Lm is measured in the same manner as the measurement method described above by the insulation resistance measurement device 1, and is stored in the storage 7A as the fourth data D4.

The operation of the insulation resistance measurement device 1A is described below together with a contact state determining method. Since the inspection processing itself is performed in the same manner as in the insulation resistance measurement device 1, description thereof is omitted, and an operation different from the determination processing of the insulation resistance measurement device 1 is described.

In the determination processing, the processor 6A measures the capacitance value of the capacitance (capacitance obtained by adding the capacitance C3 and the capacitance Cd) between the probes P1 and P2 in a contact state with the positive electrode terminal Tp and the metal layer Lm in the same manner as the measurement of the capacitance value of the capacitance C3 by the processor 6.

Subsequently, the processor 6A compares the measured capacitance value (sum of the capacitance value V_{C3} and the capacitance value V_{Cd}) of the capacitance (capacitance obtained by adding the capacitance C3 and the capacitance Cd) between the probes P1 and P₂ with the threshold value indicated by the fourth data D4 stored in the storage 7A. In this case, in at least one of when the contact between the probe P1 and the positive electrode terminal Tp is unsatisfactory and the contact resistance is high and when the contact between the probe P2 and the metal layer Lm is unsatisfactory and the contact resistance is high, since the capacitance value V_{Cd} of the capacitance Cd is measured to be small when the capacitance value of the capacitance obtained by adding the capacitance C3 and the capacitance Cd is measured, the measured capacitance value (sum of the capacitance value V_{C3} and the capacitance value V_{Cd}) of the capacitance (capacitance obtained by adding the capacitance C3 and the capacitance Cd) between the probes P1 and P2 is small. Accordingly, the processor 6A determines that the contact between the probes P1 and P2 and the positive electrode terminal Tp and the metal layer Lm is satisfactory when the measured capacitance value (sum of the capacitance value V_{C3} and the capacitance value V_{Cd}) exceeds the threshold value, and determines that the contact between the probes P1 and P2 and the positive electrode terminal Tp and the metal layer Lm is unsatisfactory when the measured capacitance value (sum of the capacitance value V_{C3} and the capacitance value V_{Cd}) is equal to or less than the threshold value.

In this way, in the insulation resistance measurement device 1A, the contact state determining device, and the contact state determining method, in the determination processing of determining whether a contact state between the probes P1 and P2 (a pair of probes), which are brought into contact with the positive electrode terminal Tp and the metal layer Lm (a pair of determination target portions) in the secondary battery DUT having the capacitance Cd between the positive electrode terminal Tp and the metal layer Lm, and the positive electrode terminal Tp and the metal layer Lm is satisfactory or unsatisfactory, when the capacitance value of capacitance (capacitance obtained by adding the capacitance C3 and the capacitance Cd) between the probes P1 and P2 in a contact state with the positive electrode terminal Tp and the metal layer Lm is measured and the measured capacitance value exceeds the threshold value (fourth data Dt4) set to a value equal to or less than the capacitance value of the capacitance between the probes P1 and P2 in a contact state with the positive electrode terminal Tp and the metal layer Lm, the contact state between the probes P1 and P2 and the positive electrode terminal Tp and the metal layer Lm is determined to be satisfactory.

Accordingly, according to the insulation resistance measurement device 1A, the contact state determining device, and the contact state determining method, the contact state can be determined only by using a simple configuration of the capacitance measurement unit (the processor 6A in this example) that can measure the capacitance value of the capacitance (capacitance obtained by adding the capacitance C3 and the capacitance Cd) between the probes P1 and P2 in a contact state with the positive electrode terminal Tp and the metal layer Lm and the processor (the processor 6A in this example) that compares the measured capacitance value with the threshold value, thereby reducing the manufacturing cost of the device and reducing the size of the device.

In addition, in the insulation resistance measurement device 1A, similarly to the insulation resistance measurement device 1, the capacitance value of the capacitance between the probes P1 and P2 can be measured using the configuration originally used for the inspection processing by the insulation resistance measurement device 1A, and as a result, an increase in the manufacturing cost of the device and an increase in the size of the device can be avoided.

In addition, in the insulation resistance measurement device 1A, by performing the discharge processing after the inspection processing in the same manner as in the insulation resistance measurement device 1, the capacitance value of the capacitance between the probes P1 and P2 can be measured within the execution time of the discharge processing originally required after the inspection processing, and as a result, extension of the inspection time can be avoided.

### Third Example

A configuration of an insulation resistance measurement device 1B is described below with reference to the drawing.

As described above, the insulation resistance measurement device 1 adopts a configuration in which the “capacitance value of the capacitance between the pair of probes in a contact state with the pair of determination target portions” is measured by the “capacitance measurement unit”, and “whether the contact state between the pair of probes and the pair of determination target portions is satisfactory or unsatisfactory” is determined based on the measured “capacitance value”, the “capacitance value of the capacitance between the pair of probes in a non-contact state with the pair of determination target portions” stored in advance in the “storage”, and the “threshold value set to a value equal to or less than the capacitance value of the capacitance between the pair of determination target portions”. In addition, the above insulation resistance measurement device 1A adopts a configuration in which the “capacitance value of the capacitance between the pair of probes in a contact state with the pair of determination target portions” is measured by the “capacitance measurement unit”, and “whether the contact state between the pair of probes and the pair of determination target portions is satisfactory or unsatisfactory” is determined based on the measured “capacitance value” and the “threshold value set to a value equal to or less than the capacitance value of the capacitance between the pair of probes in a contact state with the pair of determination target portions” stored in advance in the “storage”.

Instead of the configuration and method of determining whether the contact state is satisfactory or unsatisfactory based on the “capacitance value of the capacitance” as in the insulation resistance measurement devices 1 and 1A, a configuration and method can be adopted in which a “voltage value of a voltage between the pair of probes during discharge processing of discharging electric charge accumulated in the capacitance between the pair of probes” is measured by a “voltage measurement unit”, and “whether the contact state between the pair of probes and the pair of determination target portions is satisfactory or unsatisfactory” is determined based on the “measured voltage value” and a “reference value for determining whether the contact state between the pair of probes is satisfactory or unsatisfactory by a comparison with a comparison value specified based on the voltage value of the voltage between the pair of probes measured by the voltage measurement unit” and stored in advance in the “storage”.

As an example, the insulation resistance measurement device 1B illustrated in FIG. 1 is still another example of the inspection device having the contact state determining device, and measures insulation resistance between a pair of inspection target portions of an inspection target. Hereinafter, for example, an example in which a secondary battery DUT is set as an inspection target and a positive electrode terminal Tp and a metal layer Lm of the secondary battery DUT are set as a pair of inspection target portions (determination target portions) is described. Note that the same components and functions as those of the insulation resistance measurement devices 1 and 1A are denoted by the same reference numerals, and redundant description thereof is omitted. Since the inspection processing itself is performed in the same manner as in the insulation resistance measurement devices 1 and 1A, description thereof is omitted, and operations different from the determination processing of the insulation resistance measurement devices 1 and 1A are described.

The insulation resistance measurement device 1B includes a processor 6B and a storage 7B instead of the processors 6 and 6A and the storages 7 and 7A in the insulation resistance measurement devices 1 and 1A described above. In this case, in the insulation resistance measurement device 1B, a contact state determining device is configured by the inspection voltage generation circuit 2, the voltage-dividing circuit 3, the voltage-current detection circuit 4, the A/D converter 5a, the processor 6B, the storage 7B, and the discharge circuit 9. In the insulation resistance measurement device 1B, a voltage measurement unit is configured by the inspection voltage generation circuit 2, the voltage-dividing circuit 3, the voltage-current detection circuit 4, the A/D converter 5a, and the processor 6B.

Unlike the processors 6 and 6A, in the determination processing of determining whether a contact state between the probes P1 and P2 (a pair of probes), which are brought into contact with the positive electrode terminals Tp and the metal layer Lm (a pair of determination target portions) in the secondary battery DUT having the capacitance Cd between the positive electrode terminal Tp and the metal layer Lm, and the positive electrode terminal Tp and the metal layer Lm is satisfactory or unsatisfactory, the processor 6B of the insulation resistance measurement device 1B specifies a “comparison value” based on the voltage value of the voltage between the probes P1 and P2 during the discharge processing for discharging electric charge accumulated in the capacitance (capacitance obtained by adding the capacitance C3 and the capacitance Cd) between the probes P1 and P2 in a contact state with the positive electrode terminal Tp and the metal layer Lm, and determines whether the contact state between the probes P1 and P2 and the positive electrode terminal Tp and the metal layer Lm is satisfactory or unsatisfactory by comparing the specified “comparison value” with the “reference value” stored in the storage 7B. Specifically, the insulation resistance measurement device 1B determines whether the contact state is satisfactory or unsatisfactory in accordance with any one designated in advance among the following six processing procedures.

In a first processing procedure, a “first time” (time required for the voltage across the capacitance C3 to drop from the voltage value V1 to the voltage value V2) and a “second time” are set as the “reference value”, the “first time” being a discharge time when the electric charge accumulated between the probes P1 and P2 in a contact state with the positive electrode terminal Tp and the metal layer Lm is discharged under the same discharge conditions as the discharge processing by the discharge unit, the “second time” being set equal to or less than a discharge time (time required for the voltage across the capacitance Cd to drop from the voltage value V1 to the voltage value V2 when the electric charge accumulated in the capacitance Cd is discharged under the same discharge conditions as the discharge processing by the discharge unit) when the electric charge accumulated between the positive electrode terminal Tp and the metal layer Lm is discharged under the same discharge conditions as the discharge processing by the discharge unit, and time data Dt1 of the “first time” and time data Dt2 of the “second time” are stored in advance in the storage 7B.

In the determination processing, the processor 6B further specifies, as the “comparison value”, a “third time” (time required for the voltage between the probes P1 and P2 to drop from the voltage value V1 to the voltage value V2) being the discharge time of electric charge accumulated between the probes P1 and P2 in a contact state with the positive electrode terminal Tp and the metal layer Lm, based on the voltage value of the voltage measured by the voltage measurement unit, and determines whether the contact state between the probes P1 and P2 and the positive electrode terminal Tp and the metal layer Lm is satisfactory or unsatisfactory by comparing a “fourth time” obtained by subtracting the “first time” specified based on the time data Dt1 from the specified “third time” with the “second time” specified based on the time data Dt2.

In this case, in at least one of when the contact between the probe P1 and the positive electrode terminal Tp is unsatisfactory and the contact resistance is high and when the contact between the probe P2 and the metal layer Lm is unsatisfactory and the contact resistance is high (hereinafter, referred to as “when contact of one of the probes P1 and P2 is unsatisfactory”), no electric charge accumulated in the capacitance Cd is able to be suitably discharged by the discharge unit. The amount of electric charge discharged by the discharge processing is small compared to the state where the probes P1 and P2 are in satisfactory contact with the positive electrode terminal Tp and the metal layer Lm, respectively, and the specified “third time (discharge time)” is short. Accordingly, the processor 6B determines that the contact between the probes P1 and P2 and the positive electrode terminal Tp and the metal layer Lm is satisfactory when the “fourth time” obtained by subtracting the “first time” from the specified “third time” exceeds the “second time”, and determines that the contact between the probes P1 and P2 and the positive electrode terminal Tp and the metal layer Lm is unsatisfactory when the “fourth time” is equal to or less than the “second time”.

In a second processing procedure, a “time A” set equal to or less than a discharge time (time required for the voltage across the capacitance to drop from the voltage value V1 to the voltage value V2 when the electric charge accumulated in the capacitance obtained by adding the capacitance C3 and the capacitance Cd is discharged under the same discharge conditions as the discharge processing by the discharge unit) when the electric charge accumulated between the probes P1 and P2 in a contact state with the positive electrode terminal Tp and the metal layer Lm is discharged under the same discharge conditions as the discharge processing by the discharge unit is set as the “reference value”, and time data Dta of the “time A” is stored in advance in the storage 7B.

In the determination processing, the processor 6B further specifies, as the “comparison value”, a “time B” (time required for the voltage across the capacitance to drop from the voltage value V1 to the voltage value V2 when the electric charge accumulated in the capacitance obtained by adding the capacitance C3 and the capacitance Cd is discharged) being the discharge time of the electric charge accumulated between the probes P1 and P2 in the contact with the positive electrode terminal Tp and the metal layer Lm, based on the voltage value of the voltage measured by the voltage measurement unit, and determines whether the contact state between the probes P1 and P2 and the positive electrode terminal Tp and the metal layer Lm is satisfactory or unsatisfactory by comparing the specified “time B” with the “time A” specified based on the time data Dta.

In this case, when contact of one of the probes P1 and P2 is unsatisfactory, no electric charge accumulated in the capacitance Cd is able to be suitably discharged by the discharge unit, and the amount of electric charge discharged by the discharge processing is small compared to a state where the probes P1 and P2 are in satisfactory contact with the positive electrode terminal Tp and the metal layer Lm, respectively, and the specified “time B (discharge time)” is short. Accordingly, the processor 6B determines that the contact between the probes P1 and P2 and the positive electrode terminal Tp and the metal layer Lm is satisfactory when the “time B” exceeds the “time A”, and determines that the contact between the probes P1 and P2 and the positive electrode terminal Tp and the metal layer Lm is unsatisfactory when the “time B” is equal to or less than the “time A”.

In a third processing procedure, a “first drop rate” (ratio of the time required for the voltage across the capacitance C3 to drop from the voltage value V1 to the voltage value V2 to a difference between the voltage value V1 and the voltage value V2) and a “second drop rate” are set as the “reference value”, the “first drop rate” being a drop rate of the voltage between the probes P1 and P2 when the electric charge accumulated between the probes P1 and P2 in a non-contact state with the positive electrode terminal Tp and the metal layer Lm is discharged under the same discharge conditions as the discharge processing by the discharge unit, the “second drop rate” being set equal to or less than a drop rate (ratio of the time required for the voltage across the capacitance Cd to drop from the voltage value V1 to the voltage value V2 when the electric charge accumulated in the capacitance Cd is discharged under the same discharge conditions as the discharge processing by the discharge unit to the difference between the voltage value V1 and the voltage value V2) of the voltage between the positive electrode terminal Tp and the metal layer Lm when the electric charge accumulated between the positive electrode terminal Tp and the metal layer Lm is discharged under the same discharge conditions as the discharge processing by the discharge unit, and drop rate data Dr1 of the “first drop rate” and drop rate data Dr2 of the “second drop rate” are stored in advance in the storage 7B.

In the determination processing, the processor 6B further specifies, as the “comparison value”, a “third drop rate” (ratio of the time required for the voltage between the probes P1 and P2 to drop from the voltage value V1 to the voltage value V2 to the difference between the voltage value V1 and the voltage value V2) being a drop rate of the voltage between the probes P1 and P2 during the discharge processing on the electric charge accumulated between the probes P1 and P2 in a contact state between the positive electrode terminal Tp and the metal layer Lm, based on the voltage value measured by the voltage by the voltage measurement unit, and determines whether the contact state between the probes P1 and P2 and the positive electrode terminal Tp and the metal layer Lm is satisfactory or unsatisfactory by comparing a “fourth drop rate” obtained by subtracting the “first drop rate” specified based on the drop rate data Dr1 from the specified “third drop rate” with the “second drop rate” specified based on the drop rate data Dr2.

In this case, when contact of one of the probes P1 and P2 is unsatisfactory, no electric charge accumulated in the capacitance Cd is able to be suitably discharged by the discharge unit, the amount of electric charge discharged by the discharge processing is small compared to a state where the probes P1 and P2 are in satisfactory contact with the positive electrode terminal Tp and the metal layer Lm, respectively, the discharge time is short, and as a result, a specified voltage drop rate is high. Accordingly, the processor 6B determines that the contact between the probes P1 and P2 and the positive electrode terminal Tp and the metal layer Lm is satisfactory when the “fourth drop rate” obtained by subtracting the “first drop rate” from the specified “third drop rate” exceeds the “second drop rate”, and determines that the contact between the probes P1 and P2 and the positive electrode terminal Tp and the metal layer Lm is unsatisfactory when the “fourth drop rate” is equal to or less than the “second drop rate”.

In a fourth processing procedure, a “drop rate A” (ratio of the time required for the voltage across the capacitance to drop from the voltage value V1 to the voltage value V2 when the electric charge accumulated in the capacitance obtained by adding the capacitance C3 and the capacitance Cd is discharged under the same discharge conditions as the discharge processing by the discharge unit to the difference between the voltage value V1 and the voltage value V2) is set as the “reference value”, the “drop rate A” being set equal to or more than a drop rate of the voltage between the probes P1 and P2 when the electric charge accumulated between the probes P1 and P2 in a contact state with the positive electrode terminal Tp and the metal layer Lm is discharged under the same discharge conditions as the discharge processing by the discharge unit, and drop rate data Dra of the “drop rate A” is stored in advance in the storage 7B.

In the determination processing, the processor 6B further specifies, as the “comparison value”, a “drop rate B” (ratio of the time required for the voltage across the capacitance to drop from the voltage value V1 to the voltage value V2 when the electric charge accumulated in the capacitance obtained by adding the capacitance C3 and the capacitance Cd is discharged to the difference between the voltage value V1 and the voltage value V2) being a drop rate of the voltage between the probes P1 and P2 during the discharge processing on the electric charge accumulated between the probes P1 and P2 in a contact state with the positive electrode terminal Tp and the metal layer Lm, based on the voltage value measured by the voltage by the voltage measurement unit, and determines whether the contact state between the probes P1 and P2 and the positive electrode terminal Tp and the metal layer Lm is satisfactory or unsatisfactory by comparing the specified “drop rate B” with the “drop rate A” specified based on the drop rate data Dra.

In this case, when contact of one of the probes P1 and P2 is unsatisfactory, no electric charge accumulated in the capacitance Cd is able to be suitably discharged by the discharge unit, the amount of electric charge discharged by the discharge processing is small compared to a state where the probes P1 and P2 are in satisfactory contact with the positive electrode terminal Tp and the metal layer Lm, respectively, and the specified “time B (discharge time)” is short, and as a result, a specified voltage drop rate is high. Accordingly, the processor 6B determines that the contact between the probes P1 and P2 and the positive electrode terminal Tp and the metal layer Lm is satisfactory when the “drop rate B” exceeds the “drop rate A”, and determines that the contact between the probes P1 and P2 and the positive electrode terminal Tp and the metal layer Lm is unsatisfactory when the “drop rate B” is equal to or less than the “drop rate A”.

In a fifth processing procedure, a “first voltage value” and a “second voltage value” are set as the “reference value”, the “first voltage value” being a voltage value of the voltage between the probes P1 and P2 at the time point when a predetermined time has elapsed from the start of discharge when the electric charge (electric charge accumulated in the capacitance C3) accumulated between the probes P1 and P2 in a non-contact state with the positive electrode terminal Tp and the metal layer Lm is discharged under the same discharge conditions as the discharge processing by the discharge unit, the “second voltage value” being set equal to or less than a voltage value of the voltage between the positive electrode terminal Tp and the metal layer Lm at the time point when a predetermined time has elapsed from the start of discharge when the electric charge (electric charge accumulated in the capacitance Cd) accumulated between the positive electrode terminal Tp and the metal layer Lm is discharged under the same discharge conditions as the discharge processing by the discharge unit, and voltage value data Dv1 of the “first voltage value” and voltage value data Dv2 of the “second voltage value” are stored in advance in the storage 7B. In this case, the above “predetermined time” is set to a time (as an example, a time of about ½ of the discharge time) shorter than the discharge time of the electric charge accumulated between the probes P1 and P2 in a non-contact state with the positive electrode terminal Tp and the metal layer Lm.

In the determination processing, the processor 6B further specifies, as the “comparison value”, a “third voltage value” being a voltage value of the voltage between the probes P1 and P2 at the time point when a predetermined time has elapsed from the start of the discharge processing in the discharge processing of the electric charge accumulated between the probes P1 and P2 in a contact state with the positive electrode terminal Tp and the metal layer Lm, based on the voltage value measured by the voltage by the voltage measurement unit, and determines whether the contact state between the probes P1 and P2 and the positive electrode terminal Tp and the metal layer Lm is satisfactory or unsatisfactory by comparing a “fourth voltage value” obtained by subtracting the “first voltage value” specified based on the voltage value data Dv1 from the specified “third voltage value” with the “second voltage value” specified based on the voltage value data Dv2.

In this case, when contact of one of the probes P1 and P2 is unsatisfactory, no electric charge accumulated in the capacitance Cd is able to be suitably discharged by the discharge unit, the amount of electric charge discharged by the discharge processing is small compared to a state where the probes P1 and P2 are in satisfactory contact with the positive electrode terminal Tp and the metal layer Lm, respectively, and as a result, the voltage value of the voltage between the probes P1 and P2 decreases in a short time. Therefore, when contact of one of the probes P1 and P2 is unsatisfactory, the voltage value of the voltage between the probes P1 and P2 at the time point when the “predetermined time” has elapsed from the start of the discharge processing is low compared to the state where the probes P1 and P2 are in satisfactory contact with the positive electrode terminal Tp and the metal layer Lm, respectively. Accordingly, the processor 6B determines that the contact between the probes P1 and P2 and the positive electrode terminal Tp and the metal layer Lm is satisfactory when a “fourth voltage value” obtained by subtracting the “first voltage value” from the specified “third voltage value” exceeds the “second voltage value”, and determines that the contact between the probes P1 and P2 and the positive electrode terminal Tp and the metal layer Lm is unsatisfactory when the “fourth voltage value” is equal to or less than the “second voltage value”.

In a sixth processing procedure, a “voltage value A” is set as a “reference value”, the “voltage value A” being set equal to or less than a voltage value of the voltage between the probes P1 and P2 at the time point when a predetermined time has elapsed from the start of discharge when the electric charge (electric charge accumulated in the capacitance obtained by adding the capacitance C3 and the capacitance Cd) accumulated between the probes P1 and P2 in a contact state with the positive electrode terminal Tp and the metal layer Lm is discharged under the same discharge conditions as the discharge processing by the discharge unit, and voltage value data Dva of the “voltage value A” is stored in advance in the storage 7B. In this case, the above “predetermined time” is set to a time (as an example, a time of about ½ of the discharge time) shorter than the discharge time of the electric charge accumulated between the probes P1 and P2 in a contact state with the positive electrode terminal Tp and the metal layer Lm.

In the determination processing, the processor 6B further specifies, as the “comparison value”, a “voltage value B” being a voltage value of the voltage between the probes P1 and P2 at the time point when a predetermined time has elapsed from the start of the discharge processing in the discharge processing on the electric charge (electric charge accumulated in the capacitance obtained by adding the capacitance C3 and the capacitance Cd) accumulated between the probes P1 and P2 in a contact state with the positive electrode terminal Tp and the metal layer Lm, based on the voltage value measured by the voltage by the voltage measurement unit, and determines whether the contact state between the probes P1 and P2 and the positive electrode terminal Tp and the metal layer Lm is satisfactory or unsatisfactory by comparing the specified “voltage value B” with the “voltage value A” specified based on the voltage value data Dva.

In this case, when contact of one of the probes P1 and P2 is unsatisfactory, no electric charge accumulated in the capacitance Cd is able to be suitably discharged by the discharge unit, the amount of electric charge discharged by the discharge processing is small compared to a state where the probes P1 and P2 are in satisfactory contact with the positive electrode terminal Tp and the metal layer Lm, respectively, and as a result, the voltage value of the voltage between the probes P1 and P2 decreases in a short time. Therefore, when contact of one of the probes P1 and P2 is unsatisfactory, the voltage value of the voltage between the probes P1 and P2 at the time point when the “predetermined time” has elapsed from the start of the discharge processing is low compared to the state where the probes P1 and P2 are in satisfactory contact with the positive electrode terminal Tp and the metal layer Lm, respectively. Accordingly, the processor 6B determines that the contact between the probes P1 and P2 and the positive electrode terminal Tp and the metal layer Lm is satisfactory when the “voltage value B” exceeds the “voltage value A”, and determines that the contact between the probes P1 and P2 and the positive electrode terminal Tp and the metal layer Lm is unsatisfactory when the “voltage value B” is equal to or less than the “voltage value A”.

In this way, in the insulation resistance measurement device 1B, the contact state determining device, and the contact state determining method, in the determination processing of determining whether a contact state between the probes P1 and P2 (a pair of probes), which are brought into contact with the positive electrode terminal Tp and the metal layer Lm (a pair of determination target portions) in the secondary battery DUT having the capacitance Cd between the positive electrode terminal Tp and the metal layer Lm, and the positive electrode terminal Tp and the metal layer Lm is satisfactory or unsatisfactory, the voltage between the probes P1 and P2 is measured during the discharge processing of discharging the electric charge accumulated in the capacitance (capacitance obtained by adding the capacitance C3 and the capacitance Cd) between the probes P1 and P2 in a contact state with the positive electrode terminal Tp and the metal layer Lm, the comparison value is specified based on a voltage value of the measured voltage, and it is determined whether the contact state between the probes P1 and P2 and the positive electrode terminal Tp and the metal layer Lm is satisfactory or unsatisfactory by comparing the specified comparison value with the reference value stored in the storage.

Accordingly, according to the insulation resistance measurement device 1B, the contact state determining device, and the contact state determining method, the contact state can be determined only by using a simple configuration of the voltage measurement unit (the processor 6B in this example) that can measure the voltage between the probes P1 and P2 during the discharge processing of discharging the electric charge accumulated in the capacitance (capacitance obtained by adding the capacitance C3 and the capacitance Cd) between the probes P1 and P2 in a contact state with the positive electrode terminal Tp and the metal layer Lm, and the processor (the processor 6B in this example) that specifies the comparison value based on the measured voltage value and compares the specified comparison value with the reference value stored in the storage 7B, thereby reducing the manufacturing cost of the device and reducing the size of the device. In addition, according to the insulation resistance measurement device 1B, since the voltage value of the voltage between the probes P1 and P2 during the discharge processing can be measured using the configuration originally used for the inspection processing, an increase in the manufacturing cost of the device and an increase in the size of the device can be avoided, and since the voltage value of the voltage between the probes P1 and P2 can be measured within the execution time of the discharge processing originally required after the inspection processing, an extension of the inspection time can be avoided.

Note that the present invention is not limited to the above configuration and method, and can be modified as appropriate. For example, although an example in which the second data D2 stored in the storage 7, the fourth data D4 stored in the storage 7A, or the like are stored in the storage 7 (7A) before the execution of the inspection processing by the insulation resistance measurement device 1 (1A) has been described, the second data D2 (fourth data D4) can also be generated as a part of the inspection processing and stored in the storage 7 (storage 7A) each time.

In addition, in the insulation resistance measurement devices 1 and 1A, the processors 6 and 6A are configured to also serve as the capacitance measurement unit; however, the processor and the capacitance measurement unit can also be configured separately. Similarly, in the insulation resistance measurement device 1B, the processor 6B is configured to also serve as the voltage measurement unit; however, the processor and the voltage measurement unit can also be configured separately. In addition, the method of measuring the capacitance by the capacitance measurement unit (processors 6 and 6A) is not limited to the above method, and for example, any known measurement method such as a constant current discharge method can be adopted.

Moreover, although an example in which the determination processing of determining contact between the probes P1 and P2 and the positive electrode terminal Tp and the metal layer Lm is performed in the discharge processing after the inspection processing has been described, the determination processing can also be performed before or during the inspection processing separately from the discharge processing after the inspection processing. In addition, although an example in which the present invention is applied to an insulation resistance measurement device has been described, the present invention can also be applied to a DC withstand voltage test device. Moreover, the present invention can be widely applied to a measurement device in which a pair of probes are brought into contact with a pair of determination target portions (contact target portions) when measuring a voltage, a current, a power value, or the like.

### INDUSTRIAL APPLICABILITY

According to the present invention, since a contact state can be determined only by using a simple configuration of the capacitance measurement unit and the processor or a simple configuration of the voltage measurement unit and the processor, the manufacturing cost of the device can be reduced and the device can be miniaturized. Thus, the present invention can be widely applied to an inspection device, a contact state determining device, and a contact state determining method for determining a contact state between a pair of probes and a pair of determination target portions.

### REFERENCE SIGNS LIST

1, 1A, 1B Insulation resistance measurement device
2 Inspection voltage generation circuit
3 Voltage-dividing circuit
4 Voltage-current detection circuit
5a, 5b A/D converter
6, 6A, 6B Processor
7, 7A, 7B Storage
9 Discharge circuit
C1 Internal capacitance
C2 Wiring capacitance
C3 Capacitance
Cd Capacitance
D1 First data
D2 Second data
D3 Third data
D4 Fourth data
Dr1, Dr2, Dra Drop rate data
Dt1, Dt2, Dta Time data
Dv1, Dv2, Dva Voltage value data
DUT Secondary battery
Lm Metal layer
P1, P2 Probe
R1 Discharge resistor
Rd Insulation resistor
SW Switch
Tp Positive electrode terminal
Va Inspection DC voltage

1. An inspection device including
an inspection voltage generation unit configured to generate an inspection voltage,
a pair of probes configured to supply the inspection voltage generated by the inspection voltage generation unit between a pair of determination target portions of an inspection target in a state where the pair of probes is brought into contact with the pair of determination target portions, the inspection target having capacitance between the pair of determination target portions,
a current measurement unit configured to measure a current value of a current flowing between the pair of determination target portions in a state where the inspection voltage is supplied between the pair of determination target portions, and
a processor configured to perform inspection processing of inspecting whether the inspection target is satisfactory or unsatisfactory based on the current value of the current flowing between the pair of determination target portions measured by the current measurement unit, and determination processing of determining whether a contact state between the pair of probes brought into contact with the pair of determination target portions, and the pair of determination target portions is satisfactory or unsatisfactory, the inspection device comprising:
a storage configured to store a capacitance value of capacitance between the pair of probes in a non-contact state with the pair of determination target portions, and a threshold value set to a value equal to or less than the capacitance value of the capacitance between the pair of determination target portions;
a discharge unit configured to perform discharge processing of discharging electric charge accumulated in the capacitance between the pair of probes; and
a capacitance measurement unit configured to measure a capacitance value of capacitance between the pair of probes in a contact state with the pair of determination target portions,
wherein the processor performs the determination processing after the inspection processing, causes the capacitance measurement unit to measure the capacitance value of the capacitance between the pair of probes in a contact state with the pair of determination target portions based on a discharge time of the electric charge in the discharge processing, and determines whether the contact state between the pair of probes and the pair of determination target portions is satisfactory or unsatisfactory based on whether a capacitance value obtained by subtracting the capacitance value of the capacitance between the pair of probes stored in the storage from the capacitance value measured by the capacitance measurement unit exceeds the threshold value stored in the storage.

2. An inspection device including
an inspection voltage generation unit configured to generate an inspection voltage,
a pair of probes configured to supply the inspection voltage generated by the inspection voltage generation unit between a pair of determination target portions of an inspection target in a state where the pair of probes is brought into contact with the pair of determination target portions, the inspection target having capacitance between the pair of determination target portions,
a current measurement unit configured to measure a current value of a current flowing between the pair of determination target portions in a state where the inspection voltage is supplied between the pair of determination target portions, and
a processor configured to perform inspection processing of inspecting whether the inspection target is satisfactory or unsatisfactory based on the current value of the current flowing between the pair of determination target portions measured by the current measurement unit, and determination processing of determining whether a contact state between the pair of probes brought into contact with the pair of determination target portions, and the pair of determination target portions is satisfactory or unsatisfactory, the inspection device comprising:
a storage configured to store a threshold value set to a value equal to or less than a capacitance value of capacitance between the pair of probes in a contact state with the pair of determination target portions;
a discharge unit configured to perform discharge processing of discharging electric charge accumulated in the capacitance between the pair of probes; and
a capacitance measurement unit configured to measure a capacitance value of capacitance between the pair of probes in a contact state with the pair of determination target portions,
wherein the processor performs the determination processing after the inspection processing, causes the capacitance measurement unit to measure the capacitance value of the capacitance between the pair of probes in a contact state with the pair of determination target portions based on a discharge time of the electric charge in the discharge processing, and determines whether the contact state between the pair of probes and the pair of determination target portions is satisfactory or unsatisfactory based on whether the capacitance value measured by the capacitance measurement unit exceeds the threshold value stored in the storage.

3. An inspection device including
an inspection voltage generation unit configured to generate an inspection voltage,
a pair of probes configured to supply the inspection voltage generated by the inspection voltage generation unit between a pair of determination target portions of an inspection target in a state where the pair of probes is brought into contact with the pair of determination target portions, the inspection target having capacitance between the pair of determination target portions,
a current measurement unit configured to measure a current value of a current flowing between the pair of determination target portions in a state where the inspection voltage is supplied between the pair of determination target portions, and
a processor configured to perform inspection processing of inspecting whether the inspection target is satisfactory or unsatisfactory based on the current value of the current flowing between the pair of determination target portions measured by the current measurement unit, and determination processing of determining whether a contact state between the pair of probes brought into contact with the pair of determination target portions, and the pair of determination target portions is satisfactory or unsatisfactory, the inspection device comprising:
a discharge unit configured to perform discharge processing of discharging electric charge accumulated in the capacitance between the pair of probes;
a voltage measurement unit configured to be able to measure a voltage between the pair of probes during the discharge processing of discharging electric charge accumulated in the capacitance between the pair of probes in a contact state with the pair of determination target portions; and
a storage configured to store a reference value for determining whether a contact state between the pair of probes is satisfactory or unsatisfactory by a comparison with a comparison value specified based on a voltage value of the voltage between the pair of probes measured by the voltage measurement unit,
wherein the processor performs the determination processing after the inspection processing, specifies the comparison value based on the voltage value of the voltage measured by the voltage measurement unit during the discharge processing by the discharge unit, and determines whether the contact state between the pair of probes and the pair of determination target portions is satisfactory or unsatisfactory by comparing the comparison value specified with the reference value stored in the storage.

4. The inspection device according to claim 3, wherein
the storage stores a first time and a second time as the reference value, the first time being a discharge time when electric charge accumulated between the pair of probes in a non-contact state with the pair of determination target portions is discharged under the same discharge condition as the discharge processing, the second time being set equal to or less than a discharge time when electric charge accumulated between the pair of determination target portions is discharged under the same discharge condition as the discharge processing, and
in the determination processing, the processor specifies a third time as the comparison value, the third time being a discharge time of the electric charge accumulated between the pair of probes in a contact state with the pair of determination target portions, based on the voltage value of the voltage measured by the voltage measurement unit, and determines whether the contact state between the pair of probes and the pair of determination target portions is satisfactory or unsatisfactory by comparing a fourth time obtained by subtracting the first time from the third time specified with the second time.

5. The inspection device according to claim 3, wherein
the storage stores a time A as the reference value, the time A being set equal to or less than a discharge time when the electric charge accumulated between the pair of probes in a contact state with the pair of determination target portions is discharged under the same discharge condition as the discharge processing, and
in the determination processing, the processor specifies a time B as the comparison value, the time B being a discharge time of the electric charge accumulated between the pair of probes in a contact state with the pair of determination target portions, based on the voltage value of the voltage measured by the voltage measurement unit, and determines whether the contact state between the pair of probes and the pair of determination target portions is satisfactory or unsatisfactory by comparing the time B specified with the time A.

6. The inspection device according to claim 3, wherein
the storage stores a first drop rate and a second drop rate as the reference value, the first drop rate being a drop rate of the voltage between the pair of probes when electric charge accumulated between the pair of probes in a non-contact state with the pair of determination target portions is discharged under the same discharge condition as the discharge processing, the second drop rate being set equal to or less than a drop rate of a voltage between the pair of determination target portions when electric charge accumulated between the pair of determination target portions is discharged under the same discharge condition as the discharge processing, and
in the determination processing, the processor specifies a third drop rate as the comparison value, the third drop rate being a drop rate of the voltage between the pair of probes during the discharge processing on the electric charge accumulated between the pair of probes in a contact state with the pair of determination target portions, based on the voltage value of the voltage measured by the voltage measurement unit, and determines whether the contact state between the pair of probes and the pair of determination target portions is satisfactory or unsatisfactory by comparing a fourth drop rate obtained by subtracting the first drop rate from the third drop rate specified with the second drop rate.

7. The inspection device according to claim 3, wherein
the storage stores a drop rate A as the reference value, the drop rate A being set equal to or more than a drop rate of the voltage between the pair of probes when the electric charge accumulated between the pair of probes in a contact state with the pair of determination target portions is discharged under the same discharge condition as the discharge processing, and
in the determination processing, the processor specifies a drop rate B as the comparison value, the drop rate B being a drop rate of the voltage between the pair of probes during the discharge processing on the electric charge accumulated between the pair of probes in a contact state with the pair of determination target portions, based on the voltage value of the voltage measured by the voltage measurement unit, and determines whether the contact state between the pair of probes and the pair of determination target portions is satisfactory or unsatisfactory by comparing the drop rate B specified with the drop rate A.

8. The inspection device according to claim 3, wherein
the storage stores a first voltage value and a second voltage value as the reference value, the first voltage value being a voltage value of the voltage between the pair of probes at a time point when a predetermined time has elapsed from a discharge start when electric charge accumulated between the pair of probes in a non-contact state with the pair of determination target portions is discharged under the same discharge condition as the discharge processing, the second voltage value being set equal to or less than a voltage value of a voltage between the pair of determination target portions at a time point when the predetermined time has elapsed from a discharge start when electric charge accumulated between the pair of determination target portions is discharged under the same discharge condition as the discharge processing, and
in the determination processing, the processor specifies a third voltage value as the comparison value, the third voltage value being a voltage value of the voltage between the pair of probes at a time point when the predetermined time has elapsed from a start of the discharge processing in the discharge processing on electric charge accumulated between the pair of probes in a contact state with the pair of determination target portions, based on the voltage value of the voltage measured by the voltage measurement unit, and determines whether the contact state between the pair of probes and the pair of determination target portions is satisfactory or unsatisfactory by comparing a fourth voltage value obtained by subtracting the first voltage value from the third voltage value specified with the second voltage value.

9. The inspection device according to claim 3, wherein
the storage stores a voltage value A as the reference value, the voltage value A being set equal to or less than a voltage value of the voltage between the pair of probes at a time point when a predetermined time has elapsed from a discharge start when electric charge accumulated between the pair of probes in a contact state with the pair of determination target portions is discharged under the same discharge condition as the discharge processing, and
in the determination processing, the processor specifies a voltage value B as the comparison value, the voltage value B being a voltage value of the voltage between the pair of probes at a time point when the predetermined time has elapsed from a start of the discharge processing in the discharge processing on electric charge accumulated between the pair of probes in a contact state with the pair of determination target portions, based on the voltage value of the voltage measured by the voltage measurement unit, and determines whether the contact state between the pair of probes and the pair of determination target portions is satisfactory or unsatisfactory by comparing the voltage value B specified with the voltage value A.

10. A contact state determining device including a processor configured to perform determination processing of determining whether a contact state between a pair of probes brought into contact with a pair of determination target portions of an inspection target, and the pair of determination target portions is satisfactory or unsatisfactory, the inspection target having capacitance between the pair of determination target portions, the contact state determining device comprising:
a storage configured to store a capacitance value of capacitance between the pair of probes in a non-contact state with the pair of determination target portions, and a threshold value set to a value equal to or less than a capacitance value of the capacitance between the pair of determination target portions; and
a capacitance measurement unit configured to measure a capacitance value of capacitance between the pair of probes in a contact state with the pair of determination target portions,
wherein in the determination processing, the processor determines whether the contact state between the pair of probes and the pair of determination target portions is satisfactory or unsatisfactory based on whether a capacitance value obtained by subtracting the capacitance value of the capacitance between the pair of probes stored in the storage from the capacitance value measured by the capacitance measurement unit exceeds the threshold value stored in the storage.

11. A contact state determining device including a processor configured to perform determination processing of determining whether a contact state between a pair of probes brought into contact with a pair of determination target portions of an inspection target, and the pair of determination target portions is satisfactory or unsatisfactory, the inspection target having capacitance between the pair of determination target portions, the contact state determining device comprising:
a storage configured to store a threshold value set to a value equal to or less than a capacitance value of capacitance between the pair of probes in a contact state with the pair of determination target portions; and
a capacitance measurement unit configured to measure a capacitance value of capacitance between the pair of probes in a contact state with the pair of determination target portions,
wherein in the determination processing, the processor determines whether the contact state between the pair of probes and the pair of determination target portions is satisfactory or unsatisfactory based on whether the capacitance value measured by the capacitance measurement unit exceeds the threshold value stored in the storage.

12. A contact state determining device including a processor configured to perform determination processing of determining whether a contact state between a pair of probes brought into contact with a pair of determination target portions of an inspection target, and the pair of determination target portions is satisfactory or unsatisfactory, the inspection target having capacitance between the pair of determination target portions, the contact state determining device comprising:
a voltage measurement unit configured to measure a voltage between the pair of probes during discharge processing of discharging electric charge accumulated in capacitance between the pair of probes in a contact state with the pair of determination target portions; and
a storage configured to store a reference value for determining whether a contact state between the pair of probes is satisfactory or unsatisfactory by a comparison with a comparison value specified based on a voltage value of the voltage between the pair of probes measured by the voltage measurement unit,
wherein in the determination processing, the processor specifies the comparison value based on the voltage value of the voltage measured by the voltage measurement unit during the discharge processing, and determines whether the contact state between the pair of probes and the pair of determination target portions is satisfactory or unsatisfactory by comparing the comparison value specified with the reference value stored in the storage.

13. The contact state determining device according to claim 12, wherein
the storage stores a first time and a second time as the reference value, the first time being a discharge time when electric charge accumulated between the pair of probes in a non-contact state with the pair of determination target portions is discharged under the same discharge condition as the discharge processing, the second time being set equal to or less than a discharge time when electric charge accumulated between the pair of determination target portions is discharged under the same discharge condition as the discharge processing, and
in the determination processing, the processor specifies a third time as the comparison value, the third time being a discharge time of the electric charge accumulated between the pair of probes in a contact state with the pair of determination target portions, based on the voltage value of the voltage measured by the voltage measurement unit, and determines whether the contact state between the pair of probes and the pair of determination target portions is satisfactory or unsatisfactory by comparing a fourth time obtained by subtracting the first time from the third time specified with the second time.

14. The contact state determining device according to claim 12, wherein
the storage stores a time A as the reference value, the time A being set equal to or less than a discharge time when the electric charge accumulated between the pair of probes in a contact state with the pair of determination target portions is discharged under the same discharge condition as the discharge processing, and
in the determination processing, the processor specifies a time B as the comparison value, the time B being a discharge time of the electric charge accumulated between the pair of probes in a contact state with the pair of determination target portions, based on the voltage value of the voltage measured by the voltage measurement unit, and determines whether the contact state between the pair of probes and the pair of determination target portions is satisfactory or unsatisfactory by comparing the time B specified with the time A.

15. The contact state determining device according to claim 12, wherein
the storage stores a first drop rate and a second drop rate as the reference value, the first drop rate being a drop rate of the voltage between the pair of probes when electric charge accumulated between the pair of probes in a non-contact state with the pair of determination target portions is discharged under the same discharge condition as the discharge processing, the second drop rate being set equal to or less than a drop rate of a voltage between the pair of determination target portions when electric charge accumulated between the pair of determination target portions is discharged under the same discharge condition as the discharge processing, and
in the determination processing, the processor specifies a third drop rate as the comparison value, the third drop rate being a drop rate of the voltage between the pair of probes during the discharge processing on the electric charge accumulated between the pair of probes in a contact state with the pair of determination target portions, based on the voltage value of the voltage measured by the voltage measurement unit, and determines whether the contact state between the pair of probes and the pair of determination target portions is satisfactory or unsatisfactory by comparing a fourth drop rate obtained by subtracting the first drop rate from the third drop rate specified with the second drop rate.

16. The contact state determining device according to claim 12, wherein
the storage stores a drop rate A as the reference value, the drop rate A being set equal to or more than a drop rate of the voltage between the pair of probes when the electric charge accumulated between the pair of probes in a contact state with the pair of determination target portions is discharged under the same discharge condition as the discharge processing, and
in the determination processing, the processor specifies a drop rate B as the comparison value, the drop rate B being a drop rate of the voltage between the pair of probes during the discharge processing on the electric charge accumulated between the pair of probes in a contact state with the pair of determination target portions, based on the voltage value of the voltage measured by the voltage measurement unit, and determines whether the contact state between the pair of probes and the pair of determination target portions is satisfactory or unsatisfactory by comparing the drop rate B specified with the drop rate A.

17. The contact state determining device according to claim 12, wherein
the storage stores a first voltage value and a second voltage value as the reference value, the first voltage value being a voltage value of the voltage between the pair of probes at a time point when a predetermined time has elapsed from a discharge start when electric charge accumulated between the pair of probes in a non-contact state with the pair of determination target portions is discharged under the same discharge condition as the discharge processing, the second voltage value being set equal to or less than a voltage value of a voltage between the pair of determination target portions at a time point when the predetermined time has elapsed from a discharge start when electric charge accumulated between the pair of determination target portions is discharged under the same discharge condition as the discharge processing, and
in the determination processing, the processor specifies a third voltage value as the comparison value, the third voltage value being a voltage value of the voltage between the pair of probes at a time point when the predetermined time has elapsed from a start of the discharge processing in the discharge processing on electric charge accumulated between the pair of probes in a contact state with the pair of determination target portions, based on the voltage value of the voltage measured by the voltage measurement unit, and determines whether the contact state between the pair of probes and the pair of determination target portions is satisfactory or unsatisfactory by comparing a fourth voltage value obtained by subtracting the first voltage value from the third voltage value specified with the second voltage value.

18. The contact state determining device according to claim 12, wherein
the storage stores a voltage value A as the reference value, the voltage value A being set equal to or less than a voltage value of the voltage between the pair of probes at a time point when a predetermined time has elapsed from a discharge start when electric charge accumulated between the pair of probes in a contact state with the pair of determination target portions is discharged under the same discharge condition as the discharge processing, and
in the determination processing, the processor specifies a voltage value B as the comparison value, the voltage value B being a voltage value of the voltage between the pair of probes at a time point when the predetermined time has elapsed from a start of the discharge processing in the discharge processing on electric charge accumulated between the pair of probes in a contact state with the pair of determination target portions, based on the voltage value of the voltage measured by the voltage measurement unit, and determines whether the contact state between the pair of probes and the pair of determination target portions is satisfactory or unsatisfactory by comparing the voltage value B specified with the voltage value A.

19. (canceled)

20. (canceled)

21. (canceled)
